(19) United States
(12) Patent Application Publication
(10) Pub. No.: US 2024/0153704 A1
(43) Pub. Date: May 9, 2024

(54) ELECTRONIC COMPONENT AND METHOD FOR MANUFACTURING ELECTRONIC COMPONENT

(71) Applicant: Murata Manufacturing Co., Ltd., Kyoto-fu (JP)

(72) Inventors: Hiroaki TOKUYA, Nagaokakyo-shi (JP); Masayuki AOIKE, Nagaokakyo-shi (JP); Masahiro SHIBATA, Nagaokakyo-shi (JP)

(73) Assignee: Murata Manufacturing Co., Ltd., Kyoto-fu (JP)

(21) Appl. No.: 18/503,801

(22) Filed: Nov. 7, 2023

(30) Foreign Application Priority Data
Nov. 9, 2022 (JP) 2022-179676

(51) Int. Cl. H01G 4/08; H01G 4/30; H01G 4/33

(52) U.S. Cl. CPC H01G 4/085; H01G 4/306; H01G 4/33

(57) ABSTRACT

A capacitor including a lower layer electrode, a dielectric film, and an upper layer electrode sequentially laminated on a partial area of an upper surface serving as one surface of a substrate formed from a compound semiconductor from a side closest to the substrate is disposed. A coating formed from an insulating metal oxide or a silicon oxide is disposed on or above the dielectric film. When the upper surface is viewed in a plan, the coating extends throughout an edge of the lower layer electrode from an area inside the edge of the lower layer electrode to an area outside the edge.

### CROSS-REFERENCE TO RELATED APPLICATION

This application claims benefit of priority to Japanese Patent Application No. 2022-179676, filed Nov. 9, 2022, the entire content of which is incorporated herein by reference.

### BACKGROUND

### Technical Field

The present disclosure relates to an electronic component, and a method for manufacturing an electronic component.

### Background Art

A metal insulator metal (MIM) capacitor disposed on a silicon substrate is known as described, for example, in International Publication No. 2010/082605. The MIM capacitor described in International Publication No. 2010/082605 includes a lower electrode and an upper electrode formed from titanium nitride (TiN), and a zirconium dioxide (ZrO₂) film and a titanium dioxide (TiO₂) film to serve as dielectric films disposed between the lower electrode and the upper electrode. On side walls of the upper electrode and the dielectric films, a silicon oxide film for insulating the side walls is disposed.

### SUMMARY

Stress occurs due to a difference in coefficient of linear expansion between the substrate and the electrodes of the MIM capacitor. Stress concentrates on portions at or around the edges of a lower electrode or an upper electrode, and cracks are more likely to occur at or around these portions. When cracks are formed, they allow water to infiltrate therethrough into the MIM capacitor from the outside, and lower the reliability of the MIM capacitor.

Accordingly, the present disclosure provides an electronic component including a capacitor that reduces lowering of reliability even in the presence of cracks.

An aspect of the present disclosure provides an electronic component including a substrate formed from a compound semiconductor; a capacitor including a lower layer electrode, a dielectric film, and an upper layer electrode sequentially laminated, from a side closest to the substrate, on a partial area of an upper surface serving as one surface of the substrate; and a coating disposed on or above the dielectric film, the coating extending, when the upper surface is viewed in a plan, throughout an edge of the lower layer electrode from an area inside the edge of the lower layer electrode to an area outside the edge, and the coating being formed from an insulating metal oxide or a silicon oxide.

Another aspect of the present disclosure provides a method for manufacturing an electronic component, the method including forming a lower layer electrode on an upper surface serving as one surface of a substrate formed from a compound semiconductor; forming a dielectric film on the lower layer electrode; forming an upper layer electrode on the dielectric film; and forming a coating from an insulating metal oxide or a silicon oxide after forming the dielectric film and before forming the upper layer electrode, or after forming the upper layer electrode, to extend the coating throughout an edge of the lower layer electrode, when the upper surface is viewed in a plan, to an area outside an edge of the lower layer electrode from an area inside the edge.

The coating reduces water infiltrating into the lower layer electrode, the upper layer electrode, and the dielectric film. Thus, the electronic component can reduce lowering of the reliability.

### BRIEF DESCRIPTION OF THE DRAWINGS

FIG. 1 is a diagram illustrating a planar positional relationship between components in an electronic component according to a first embodiment;

FIGS. 2A and 2B are cross-sectional views of the electronic component taken along dot-and-dash line 2A-2A and dot-and-dash line 2B-2B in FIG. 1;

FIG. 3 is a graph illustrating measurement results of reliability of electronic components according to a comparative example and an embodiment;

FIG. 4 is a graph illustrating measurement results of an oxygen atom concentration of a dielectric film under a coating in electronic components according to a comparative example and an embodiment;

FIGS. 5A, 5B, and 5C are diagrams illustrating a planar positional relationship between components in electronic components according to multiple modification examples of the first embodiment;

FIGS. 6A and 6B are cross-sectional views of an electronic component according to a second embodiment; and

FIGS. 7A and 7B are cross-sectional views of an electronic component according to a third embodiment.

### DETAILED DESCRIPTION

### First Embodiment

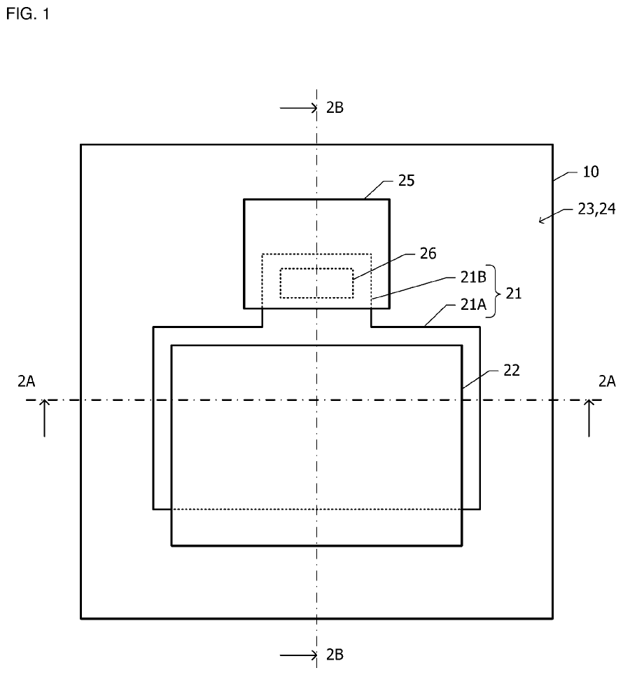

With reference to FIGS. 1 to 4, an electronic component according to a first embodiment is described.

FIG. 1 is a diagram illustrating a planar positional relationship between components in the electronic component according to the first embodiment. A lower layer electrode 21 is disposed on a partial area of an upper surface serving as one edge of a substrate 10 formed from a compound semiconductor. When the upper surface of the substrate 10 is viewed in a plan (hereinafter referred to as “in a plan view”), the lower layer electrode 21 includes a main portion 21A that is substantially rectangular in a plan view, and a protrusion 21B that protrudes outward from the center of one side of the main portion 21A.

An upper layer electrode 22 is disposed to overlap the main portion 21A of the lower layer electrode 21, and an extended wire 25 is disposed to overlap the protrusion 21B. Between the lower layer electrode 21 and the upper layer electrode 22, and between the lower layer electrode 21 and the extended wire 25, a dielectric film 23 and a coating 24 are disposed, as described below. The dielectric film 23 and the coating 24 overlap the entirety of the edge of the lower layer electrode 21 in a plan view, and extend throughout the edge of the lower layer electrode 21 from the area inside the edge of the lower layer electrode 21 to the area outside the edge. The coating 24 does not have to be disposed throughout the area inside the edge of the lower layer electrode 21. Here, “inside the edge of a specific portion” indicates an area inside a border, using the edge of the portion in a plan view as the border, and “outside the edge of a specific portion” indicates an area outside a border, using the edge of the portion in a plan view as the border.

In a plan view, the edge of the upper layer electrode 22 is disposed at a position shifted from the edge of the lower layer electrode 21. For example, the edge of the upper layer electrode 22 is disposed at a position shifted inward from the edge of the lower layer electrode 21 at, among four sides of the main portion 21A of the lower layer electrode 21, the side from which the protrusion 21B protrudes and the two sides adjacent to the side from which the protrusion 21B protrudes. At the remaining one side, the edge of the upper layer electrode 22 is disposed at a position shifted outward from the edge of the main portion 21A of the lower layer electrode 21. The extended wire 25 is connected to the lower layer electrode 21 through a cavity 26 formed in a dielectric film under the extended wire 25.

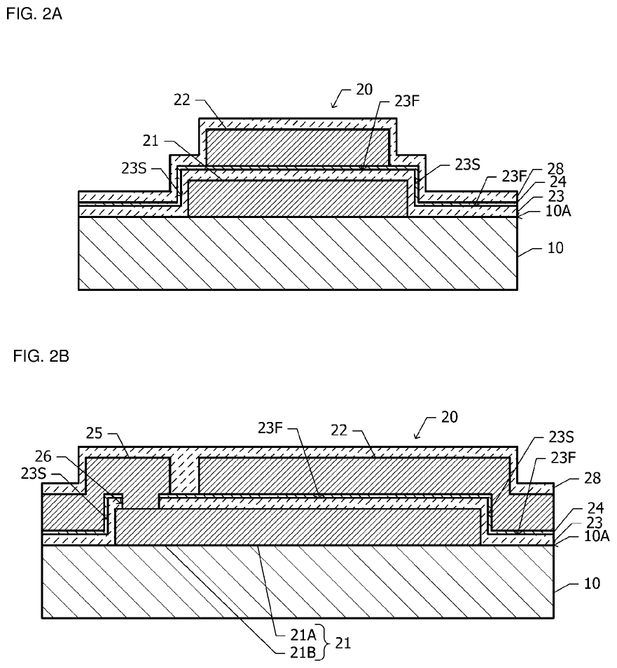

FIGS. 2A and 2B are cross-sectional views of the electronic component taken along dot-and-dash line 2A-2A and dot-and-dash line 2B-2B in FIG. 1. The lower layer electrode 21 is disposed in a partial area of an upper surface 10A serving as one surface of the substrate 10 formed from a compound semiconductor. The dielectric film 23 is disposed to cover the upper surface 10A of the substrate 10 and the lower layer electrode 21. For example, the dielectric film 23 is disposed throughout the upper surface 10A of the substrate 10.

An undercoat surface of the dielectric film 23 (a lower surface of the dielectric film 23) includes a step formed from side surfaces of the lower layer electrode 21. The upper surface of the dielectric film 23 includes flat areas 23F, covering the upper surface of the lower layer electrode 21 and the upper surface 10A of the substrate 10 in the area where the lower layer electrode 21 is not disposed, and a step area 23S on which the step formed from the side surfaces of the lower layer electrode 21 is reflected. The flat areas 23F on the upper surface of the dielectric film 23 are parallel to the upper surface 10A of the substrate 10. Here, “being parallel” does not indicate being geometrically parallel in a strict sense, but indicates the meaning including a relation not being parallel in a strict sense but within an allowable range due to, for example, variations caused during a manufacturing process.

The insulating coating 24 is disposed on the dielectric film 23. The insulating coating 24 covers, in a conformal manner, the step area 23S and the flat areas 23F in the upper surface of the dielectric film 23 serving as the undercoat surface of the coating 24. For example, the coating 24 covering the flat areas 23F has an equal thickness to the coating 24 covering the step area 23S. Here, “having an equal thickness” indicates that, for example, irrespective of the shape of the undercoat surface, the film formed under the conditions where both the flat areas 23F and the step area 23S have an equal film thickness has an equal thickness between the portions above the flat areas 23F and the portion above the step area 23S. The case where the film has a difference in film thickness of the level resulting from the variation within an allowable range due to a deposition process can also be regarded as “having an equal thickness”. The thickness of the coating 24 is, for example, larger than or equal to 1 nm and smaller than or equal to 20 nm (i.e., from 1 nm to 20 nm), and smaller than the thickness of the dielectric film 23 at any portion in the area covered with the coating 24.

The upper layer electrode 22 and the extended wire 25 are disposed on portions of the coating 24. A portion of the upper layer electrode 22 overlaps the main portion 21A of the lower layer electrode 21 in a plan view. The lower layer electrode 21, the upper layer electrode 22, and the dielectric film 23 disposed between the lower layer electrode 21 and the upper layer electrode 22 form an MIM capacitor. A portion of the extended wire 25 overlaps the protrusion 21B of the lower layer electrode 21 in a plan view, and is connected to the lower layer electrode 21 through the cavity 26 formed in the dielectric film 23 and the coating 24. An insulator film 28 covers the upper layer electrode 22, the extended wire 25, and the coating 24.

Subsequently, the materials of components in the electronic component are described.

A compound semiconductor substrate, such as a semi-insulating GaAs substrate is used as the substrate 10. A substrate including an undercoat substrate and an insulating layer or an epitaxially grown layer formed on the substrate may be used as the substrate 10. For example, a metal material such as Au, Ti, Pt, or W is used for the lower layer electrode 21, the upper layer electrode 22, and the extended wire 25. For example, a silicon nitride (SiN) is used for the dielectric film 23. The dielectric film 23 may include oxygen as an impurity.

An insulating metal oxide or a silicon oxide (SiO₂) is used for the coating 24. Examples of an insulating metal oxide include an aluminium oxide (Al₂O₃), a hafnium oxide (HfO₂), a zirconium oxide (ZrO₂), a titanium oxide (TiO₂), a tantalum oxide (Ta₂O₅), a gallium oxide (Ga₂O₃), a zinc oxide (ZnO), and a strontium titanate (SrTiO₃). The actual coating 24 may have a composition different from the stoichiometric composition of the corresponding one of chemical formulae in parentheses.

Subsequently, with reference to FIGS. 2A and 2B, a method for manufacturing the electronic component according to the first embodiment is described. First, the lower layer electrode 21 is formed in a partial area of the upper surface 10A of the substrate 10. The lower layer electrode 21 is deposited by, for example, sputtering, vapor deposition, or plating. The dielectric film 23 is formed on the lower layer electrode 21 and the substrate 10. The dielectric film 23 is formed by, for example, plasma chemical-vapor deposition (CVD). A portion of the dielectric film 23 is removed by etching to form the cavity 26. When the dielectric film 23 is formed by plasma CVD, the step area 23S has a smaller thickness than the flat areas 23F.

The coating 24 is formed on the dielectric film 23. The coating 24 is formed by, for example, atomic layer deposition (ALD). ALD enables deposition of the coating 24 with substantially the even thickness over the flat areas 23F and the step area 23S on the upper surface of the dielectric film 23, and enables formation of a minute film. After the coating 24 is formed, a portion of the coating 24 is removed by etching to form the cavity 26. After the dielectric film 23 and the coating 24 are formed, portions of these two layers may be collectively removed by etching to form the cavity 26.

The upper layer electrode 22 and the extended wire 25 are formed on the coating 24. The upper layer electrode 22 and the extended wire 25 are formed by, for example, sputtering, vapor deposition, or plating. The insulator film 28 is formed to cover the upper layer electrode 22 and the extended wire 25. The insulator film 28 is formed by, for example, plasma CVD.

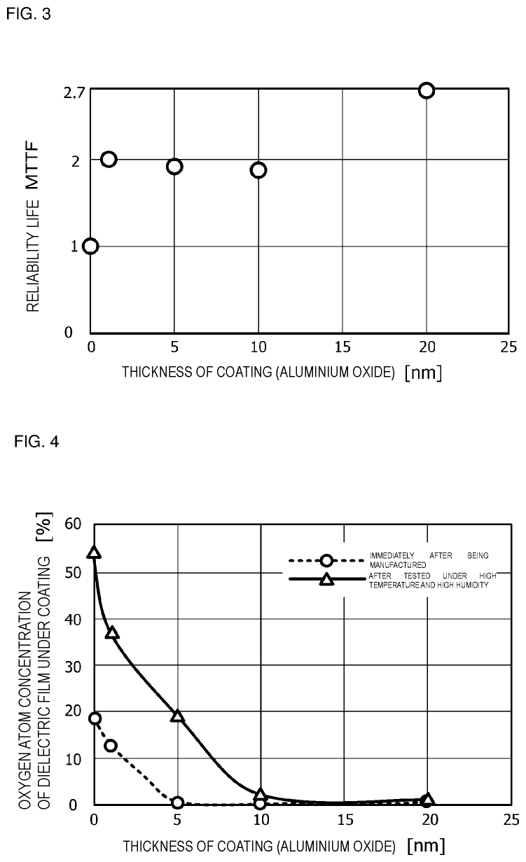

Subsequently, with reference to FIGS. 3 and 4, advantageous effects of the first embodiment are described.

Thermal stress occurs due to a difference in coefficient of linear expansion between the substrate 10 and the lower layer electrode 21 and the upper layer electrode 22. Thermal stress is more likely to be particularly concentrated on a portion near the step formed from the side surfaces of the upper layer electrode 22 and the lower layer electrode 21. Thus, cracks are more likely to occur in the insulator film 28 or the dielectric film 23 near the step of the upper layer electrode 22, and cracks are more likely to occur in the insulator film 28 or the dielectric film 23 near the step of the lower layer electrode 21. When, for example, a crack occurs in the insulator film 28, the crack allows water to infiltrate therethrough into an MIM capacitor 20, and reduces reliability of the MIM capacitor.

When water infiltrates into the dielectric film 23, the dielectric film 23 deteriorates, and the electric characteristics of the MIM capacitor 20 deviate from the target characteristics.

In the electronic component according to the first embodiment, the coating 24 functions as a barrier film to reduce infiltration of water. Thus, even in the presence a crack, the crack is less likely to allow water to infiltrate therethrough into the lower layer electrode 21 and the dielectric film 23 of the MIM capacitor 20, and the MIM capacitor can thus reduce lowering of the reliability.

Normally, the coefficient of linear expansion of the coating 24 formed from a metal oxide is higher than the linear expansion coefficient of the dielectric film 23 formed from a silicon nitride. To reduce the effect of thermal stress attributable to the difference in coefficient of linear expansion between the dielectric film 23 and the coating 24, the coating 24 is preferably thinner than the dielectric film 23, and the thickness of the coating 24 is more preferably smaller than or equal to 1/10 of the thickness of portions of the dielectric film 23 corresponding to the flat areas 23F.

FIG. 3 is a graph illustrating measurement results of reliability of electronic components according to a comparative example and an embodiment. The horizontal axis indicates the thickness of the coating 24 (FIGS. 2A and 2B) in nanometer [nm], and the vertical axis indicates reliability life MTTF in normalized units with a thickness of the coating 24 of 20 nm as the reference value of 1. Samples of the coating 24 with a thickness of 0 nm (comparative example), 1 nm, 5 nm, 10 nm, and 20 nm were formed from an aluminium oxide. It is found that the structure including the coating 24 has longer MTTF than a structure not including the coating 24. Particularly, when the thickness of the coating 24 is greater than or equal to 1 nm, the structure has an effect of elongating MTTF. Depositing the coating 24 with a larger thickness takes a longer time. The coating 24 with a thickness larger than necessary does not largely change the effect of enhancing reliability. To obtain a sufficiently large effect of enhancing reliability while reducing an increase of time for deposition, the thickness of the coating 24 is preferably smaller than or equal to 20 nm.

FIG. 4 is a graph illustrating measurement results of an oxygen atom concentration of the dielectric film 23 under the coating 24 in electronic components according to a comparative example and an embodiment. The horizontal axis indicates the thickness of the coating 24 (FIGS. 2A and 2B) in nanometer [nm], and the vertical axis indicates the oxygen atom concentration in “atom concentration percent (atm %) of O1s”. The oxygen concentration was measured with X-ray photoelectron spectroscopy. A sample of the coating 24 with a thickness of 0 nm corresponds to a comparative example.

Circles and a broken line in FIG. 4 indicate values measured immediately after being manufactured, and triangles and a solid line indicate values measured after being tested under high temperature and high humidity. In either measurement immediately after being manufactured or after being tested under high temperature and high humidity, it is found that the oxygen concentration decreases with the increase of the thickness of the coating 24. This indicates reduction of infiltration of water.

Evaluation experiment results illustrated in FIG. 3 and FIG. 4 have revealed that the coating 24 reduces infiltration of water and lowering of reliability.

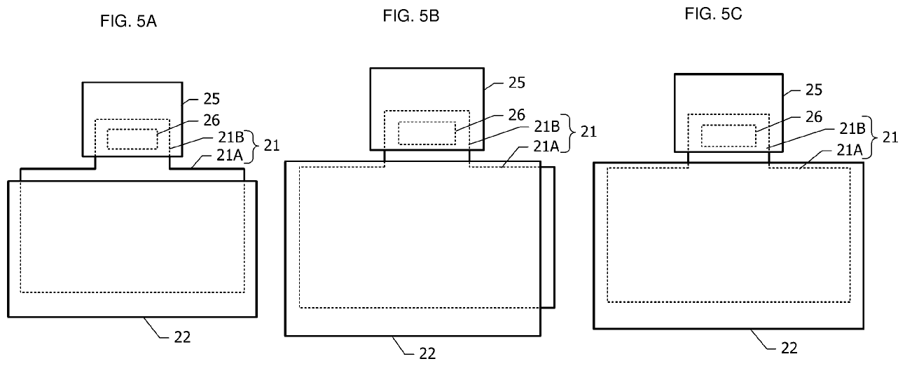

With reference to FIG. 5A, FIG. 5B, and FIG. 5C, electronic components according to modification examples of the first embodiment are described. FIGS. 5A, 5B, and 5C are diagrams illustrating the planar positional relationship between components in electronic components according to multiple modification examples of the first embodiment.

In the first embodiment (FIG. 1), the edge of the upper layer electrode 22 is disposed at a position shifted from the edge of the lower layer electrode 21, the three sides of the upper layer electrode 22 are disposed at positions shifted inward from the corresponding sides of the lower layer electrode 21, and the remaining one side is disposed at a position shifted outward from the corresponding side of the lower layer electrode 21. The modification examples illustrated in FIG. 5A, FIG. 5B, and FIG. 5C differ in the positional relationship between the sides of the lower layer electrode 21 and the sides of the upper layer electrode 22.

In the modification example illustrated in FIG. 5A, the three sides of the upper layer electrode 22 corresponding to the three sides of the main portion 21A of the lower layer electrode 21 at which the protrusion 21B is not disposed are disposed at positions shifted outward from the corresponding three sides of the main portion 21A of the lower layer electrode 21. One side of the upper layer electrode 22 corresponding to the side of the main portion 21A of the lower layer electrode 21 at which the protrusion 21B is disposed is disposed at a position shifted inward from the corresponding side of the main portion 21A of the lower layer electrode 21.

In the modification example illustrated in FIG. 5B, three sides of the upper layer electrode 22 corresponding to the side of the main portion 21A of the lower layer electrode 21 at which the protrusion 21B is disposed, the side of the main portion 21A opposite to the side at which the protrusion 21B is disposed, and another side of the main portion 21A are disposed at positions shifted outward from the corresponding three sides of the main portion 21A of the lower layer electrode 21. The remaining one side of the upper layer electrode 22 is disposed at a position shifted inward from the corresponding side of the main portion 21A of the lower layer electrode 21.

In the modification example illustrated in FIG. 5C, the four sides of the upper layer electrode 22 are disposed at positions shifted outward from the corresponding four sides of the main portion 21A of the lower layer electrode 21. Specifically, in a plan view, the upper layer electrode 22 covers the main portion 21A of the lower layer electrode 21.

Also in the modification examples illustrated in FIG. 5A, FIG. 5B, and FIG. 5C, stress concentration can be reduced by shifting the edge of the upper layer electrode 22 from the edge of the lower layer electrode 21 in a plan view. These examples can thus reduce occurrence of cracks.

In the modification example of the first embodiment illustrated in FIG. 5C, the entirety of the edge of the main portion 21A of the lower layer electrode 21 is covered with, not only the coating 24 (FIG. 2A and FIG. 2B) but also the upper layer electrode 22. Thus, even in the presence of cracks, the structure of this example can enhance the effect of reducing water infiltrating into the lower layer electrode 21 and the dielectric film 23 of the MIM capacitor 20.

### Second Embodiment

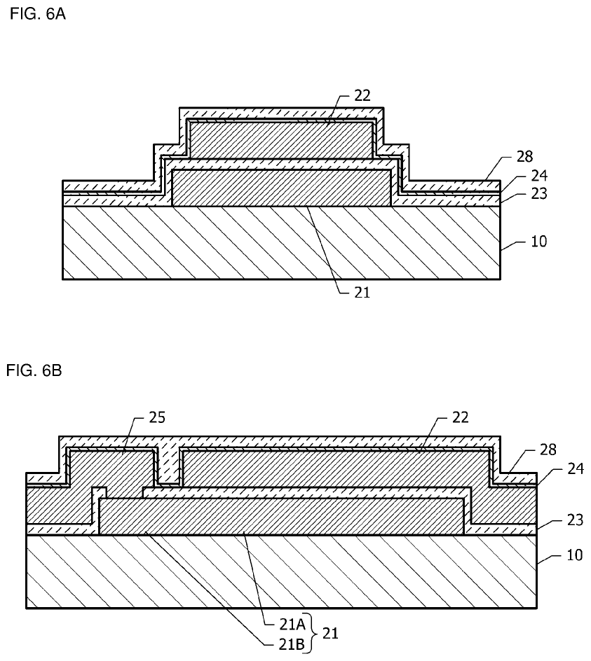

An electronic component according to a second embodiment is described with reference to FIG. 6A and FIG. 6B. Hereinbelow, the same components as those in the electronic component according to the first embodiment described with reference to FIG. 1 to FIG. 4 are not described.

FIGS. 6A and 6B are cross-sectional views of an electronic component according to a second embodiment. FIGS. 6A and 6B respectively correspond to the cross-sectional views taken along dot-and-dash line 2A-2A and dot-and-dash line 2B-2B in FIG. 1.

In the first embodiment (FIG. 2A and FIG. 2B), the coating 24 is disposed between the dielectric film 23 and the upper layer electrode 22, and between the extended wire 25 and the dielectric film 23. In the area where the upper layer electrode 22 and the extended wire 25 are not disposed, the coating 24 is disposed between the dielectric film 23 and the insulator film 28. In contrast, in the second embodiment, the coating 24 is disposed between the upper layer electrode 22 and the insulator film 28, and between the extended wire 25 and the insulator film 28. As in the first embodiment, the coating 24 is disposed between the dielectric film 23 and the insulator film 28 in an area where the upper layer electrode 22 and the extended wire 25 are not disposed.

Also in the second embodiment, the coating 24 extends throughout the edge of the lower layer electrode 21 in a plan view from the area inside the edge of the lower layer electrode 21 to the area outside the edge. Thus, as in the first embodiment, the structure according to the second embodiment is less likely to allow water to infiltrate into the lower layer electrode 21 and the dielectric film 23. Thus, the structure can reduce lowering of the reliability due to infiltration of water.

In the second embodiment, the coating 24 covers the upper layer electrode 22, and extends throughout the edge of the upper layer electrode 22, in a plan view, from the area inside the edge of the upper layer electrode 22 to the area outside the edge. Thus, this structure can also reduce water infiltrating into the upper layer electrode 22, in addition to the lower layer electrode 21 and the dielectric film 23.

### Third Embodiment

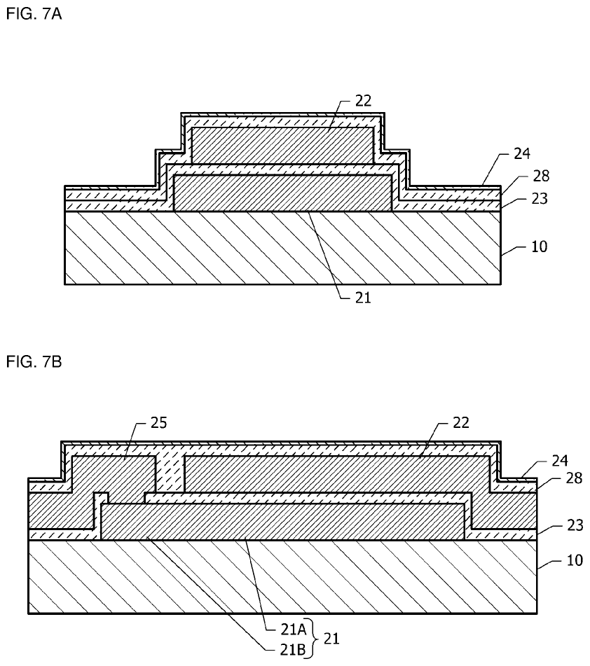

Subsequently, an electronic component according to a third embodiment is described with reference to FIG. 7A and FIG. 7B. Hereinbelow, the same components as those in the electronic component according to the first embodiment described with reference to FIG. 1 to FIG. 4 are not described.

FIGS. 7A and 7B are cross-sectional views of an electronic component according to a third embodiment. FIGS. 7A and 7B respectively correspond to the cross-sectional views taken along dot-and-dash line 2A-2A and dot-and-dash line 2B-2B in FIG. 1.

In the first embodiment (FIG. 2A and FIG. 2B), the coating 24 is disposed between the dielectric film 23 and the upper layer electrode 22, and between the extended wire 25 and the dielectric film 23. In the area where the upper layer electrode 22 and the extended wire 25 are not disposed, the coating 24 is disposed between the dielectric film 23 and the insulator film 28. In contrast, in the third embodiment, the coating 24 is disposed on the insulator film 28.

Also in the third embodiment, the coating 24 extends throughout the edge of the lower layer electrode 21 in a plan view from the area inside the edge of the lower layer electrode 21 to the area outside the edge. Thus, as in the first embodiment, the structure according to the third embodiment is less likely to allow water to infiltrate into the lower layer electrode 21 and the dielectric film 23. Thus, the structure can reduce lowering of the reliability due to infiltration of water.

Also in the third embodiment, as in the second embodiment, the coating 24 covers the upper layer electrode 22 with the insulator film 28 interposed therebetween, and extends throughout the edge of the upper layer electrode 22, in a plan view, from the area inside the edge of the upper layer electrode 22 to the area outside the edge. Thus, this structure is less likely to allow water to infiltrate into the upper layer electrode 22, the insulator film 28, and the lower layer electrode 21.

The above embodiments are mere examples, and any two or more of components between different embodiments may naturally be switched with each other or combined with each other. The same operation effects from the same components among multiple embodiments are not described separately for each embodiment. The present disclosure is not limited to the above embodiments. For example, it is apparent to those having ordinary skill in the art that each embodiment can be changed, improved, or combined in various manners.

Based on the embodiments described herein, the following disclosure is disclosed.

<1> An electronic component comprising a substrate formed from a compound semiconductor; a capacitor including a lower layer electrode, a dielectric film, and an upper layer electrode sequentially laminated, from a side closest to the substrate, on a partial area of an upper surface serving as one surface of the substrate; and a coating disposed on or above the dielectric film, the coating extending, when the upper surface is viewed in a plan, throughout an edge of the lower layer electrode from an area inside the edge of the lower layer electrode to an area outside the edge, and the coating being formed from an insulating metal oxide or a silicon oxide.

<2> The electronic component according to <1>, wherein the coating is thinner than the dielectric film.

<3> The electronic component according to <1> or <2>, wherein an undercoat surface of the coating includes a flat area parallel to the upper surface of the substrate, and a step area on which the step formed from the side surfaces of the lower layer electrode is reflected. Also, a thickness of a portion of the coating covering the step area is equal to a thickness of a portion of the coating covering the flat area.

<4> The electronic component according to any one of <1> to <3>, wherein a metal oxide forming the coating is at least one selected from the group consisting of an aluminium oxide, a hafnium oxide, a zirconium oxide, a titanium oxide, a tantalum oxide, a gallium oxide, a zinc oxide, and a strontium titanate.

<5> The electronic component according to any one of <1> to <4>, wherein the coating is disposed between the dielectric film and the upper layer electrode.

<6> The electronic component according to any one of <1> to <4>, wherein the coating is disposed on the upper layer electrode.

<7> The electronic component according to <6>, further comprising an insulator film disposed between the upper layer electrode and the coating.

<8> The electronic component according to any one of <1> to <7>, wherein when the upper surface is viewed in a plan, an edge of the lower layer electrode and an edge of the upper layer electrode are disposed at positions shifted from each other.

<9> The electronic component according to <8>, wherein when the upper surface is viewed in a plan, a portion of the edge of the upper layer electrode is disposed inward from the edge of the lower layer electrode, and a remaining portion of the edge is disposed outward from the edge of the lower layer electrode.

<10> The electronic component according to <8>, wherein when the upper surface is viewed in a plan, an entirety of the edge of the upper layer electrode is disposed outward from the edge of the lower layer electrode.

<11> The electronic component according to any one of <1> to <10>, wherein the compound semiconductor forming the substrate is GaAs.

<12> A method for manufacturing an electronic component, the method comprising forming a lower layer electrode on an upper surface serving as one surface of a substrate formed from a compound semiconductor; forming a dielectric film on the lower layer electrode; forming an upper layer electrode on the dielectric film; and forming a coating from an insulating metal oxide or a silicon oxide after forming the dielectric film and before forming the upper layer electrode, or after forming the upper layer electrode, to extend the coating throughout an edge of the lower layer electrode, when the upper surface is viewed in a plan, from an area inside the edge of the lower layer electrode to an area outside the edge.

<13> The method according to <12>, wherein the coating is formed by atomic layer deposition.

What is claimed is:

1. An electronic component comprising:
a substrate including a compound semiconductor;
a capacitor including a lower layer electrode, a dielectric film, and an upper layer electrode sequentially laminated, from a side closest to the substrate, on a partial area of an upper surface serving as one surface of the substrate; and
a coating on or above the dielectric film, the coating extending, when the upper surface is viewed in plan, throughout an edge of the lower layer electrode from an area inside the edge of the lower layer electrode to an area outside the edge, and the coating including an insulating metal oxide or a silicon oxide.

2. The electronic component according to claim 1, wherein
the coating is thinner than the dielectric film.

3. The electronic component according to claim 1, wherein
an undercoat surface of the coating includes a flat area parallel to the upper surface of the substrate, and a step area on which a step is defined from side surfaces of the lower layer electrode, and
a thickness of a portion of the coating covering the step area is equal to a thickness of a portion of the coating covering the flat area.

4. The electronic component according to claim 1, wherein
a metal oxide of the coating is at least one of an aluminium oxide, a hafnium oxide, a zirconium oxide, a titanium oxide, a tantalum oxide, a gallium oxide, a zinc oxide, and a strontium titanate.

5. The electronic component according to claim 1, wherein
the coating is between the dielectric film and the upper layer electrode.

6. The electronic component according to claim 1, wherein
the coating is on the upper layer electrode.

7. The electronic component according to claim 6, further comprising:
an insulator film between the upper layer electrode and the coating.

8. The electronic component according to claim 1, wherein
when the upper surface is viewed in plan, an edge of the lower layer electrode and an edge of the upper layer electrode are at positions shifted from each other.

9. The electronic component according to claim 8, wherein
when the upper surface is viewed in plan, a portion of the edge of the upper layer electrode is inward from the edge of the lower layer electrode, and a remaining portion of the edge of the upper layer electrode is outward from the edge of the lower layer electrode.

10. The electronic component according to claim 8, wherein
when the upper surface is viewed in plan, an entirety of the edge of the upper layer electrode is outward from the edge of the lower layer electrode.

11. The electronic component according to claim 1, wherein
the compound semiconductor of the substrate is GaAs.

12. The electronic component according to claim 2, wherein
an undercoat surface of the coating includes a flat area parallel to the upper surface of the substrate, and a step area on which a step is defined from side surfaces of the lower layer electrode, and
a thickness of a portion of the coating covering the step area is equal to a thickness of a portion of the coating covering the flat area.

13. The electronic component according to claim 2, wherein
a metal oxide of the coating is at least one of an aluminium oxide, a hafnium oxide, a zirconium oxide, a titanium oxide, a tantalum oxide, a gallium oxide, a zinc oxide, and a strontium titanate.

14. The electronic component according to claim 2, wherein
the coating is between the dielectric film and the upper layer electrode.

15. The electronic component according to claim 2, wherein
the coating is on the upper layer electrode.

16. The electronic component according to claim 15, further comprising:
an insulator film between the upper layer electrode and the coating.

17. The electronic component according to claim 2, wherein
when the upper surface is viewed in plan, an edge of the lower layer electrode and an edge of the upper layer electrode are at positions shifted from each other.

18. The electronic component according to claim 2, wherein
the compound semiconductor of the substrate is GaAs.

19. A method for manufacturing an electronic component, the method comprising:
forming a lower layer electrode on an upper surface serving as one surface of a substrate formed from a compound semiconductor;
forming a dielectric film on the lower layer electrode;
forming an upper layer electrode on the dielectric film; and
forming a coating from an insulating metal oxide or a silicon oxide after forming the dielectric film and before forming the upper layer electrode, or after forming the upper layer electrode, to extend the coating throughout an edge of the lower layer electrode, when the upper surface is viewed in plan, from an area inside the edge of the lower layer electrode to an area outside the edge.

20. The method according to claim 19,
wherein the coating is formed by atomic layer deposition.
